(19) United States
(12) Patent Application Publication
(10) Pub. No.: US 2026/0313780 A1
(43) Pub. Date: Oct. 8, 2026

(54) ENHANCED THERMAL MANAGEMENT IN HIGH-POWER ELECTRONICS USING PHASE CHANGE MATERIALS

(71) Applicant: Connaught Electronics Ltd., Tuam (IE)

(72) Inventors: Andrew DRAPER, Troy, MI (US); Roman RODRICKSELVARAVI, Tuam, County Galway (IE); Basheerahmed SHIHABUDEEN, Troy, MI (US); Jerin WILLIAM JAMES, Chennai (IN)

(21) Appl. No.: 19/169,303

(22) Filed: Apr. 3, 2025

(51) Int. Cl. H05K 1/02; B60H 1/00

(52) U.S. Cl. CPC H05K 1/0203; B60H 1/00328; H05K 2201/064; H05K 2201/066

(57) ABSTRACT

A thermal management system for vehicle electronics addresses challenges of fail-safe cooling in high-power electronic systems. The system includes printed circuit boards (PCB) with a heat-generating components. A phase change material (PCM) absorbs heat generated by the heat-generating component, providing a thermal buffer during coolant system failures. The PCM can be provided in various locations and configurations, such as on an opposing side of the PCB from the heat-generating component, within the fluid channels themselves or remotely situated on a heat-spreader.

### TECHNICAL FIELD

The present disclosure relates to thermal management systems for high-power electronic systems. In specific embodiments, the present disclosure relates to cooling solutions for vehicle components such as Central Compute Units (CCUs) or Electronic Control Units (ECUs) using phase change materials.

### BACKGROUND

In the realm of high-power electronic systems, particularly those utilized in automated vehicles, effective thermal management is necessary to ensure operational reliability and safety. Current cooling systems predominantly rely on liquid cooling methods to dissipate heat from components such as System-on-Chips (SoCs). While these systems are generally effective under typical conditions, they are vulnerable to catastrophic failures in the event of coolant loss. Such failures can lead to rapid temperature increases, resulting in system shutdowns within seconds. This poses significant safety risks, especially in automated vehicles where continuous operation of important functionalities is required.

Existing solutions that incorporate phase change materials (PCMs) into cooling systems often introduce unwanted thermal resistance during typical operation, potentially hindering performance. These solutions may not adequately address the need for a thermal management system that provides both efficient cooling under standard conditions and a robust safeguard against rapid temperature increases during coolant system failures. Challenges lie in developing solutions that enhances safety and reliability without compromising the performance of high-power electronic systems.

### SUMMARY

In an embodiment, a thermal management system for vehicle electronics comprises a printed circuit board (PCB) having an upper side and a lower side; a heat-generating component having an upper side and a lower side, wherein the upper side of the heat-generating component is mounted on the lower side of the PCB; and a phase change material (PCM) positioned on the upper side of the PCB at a location that is vertically aligned with the heat-generating component, wherein the PCM absorbs heat conducted through the PCB from the heat-generating component.

In an embodiment, a thermal management system for vehicle electronics comprises a printed circuit board (PCB) having an upper side and a lower side; a heat-generating component having an upper side and a lower side, wherein the upper side of the heat-generating component is mounted on the lower side of the PCB; a heat sink contacting the lower side of the heat-generating component, wherein the heat sink defines cooling channels beneath the heat-generating component, wherein the cooling channels are configured to facilitate the flow of coolant directly underneath the heat-generating component to absorb and dissipate heat generated by the heat-generating component; and a phase change material (PCM) embedded in the heat sink.

In an embodiment, a thermal management system for vehicle electronics comprises a printed circuit board (PCB) having an upper side and a lower side; a housing located beneath the PCB and defining a cavity therebetween; a heat-generating component located within the cavity and mounted on the lower side of the PCB; a first phase change material (PCM) located between the housing and the PCB; and a plurality of pipes connecting the heat-generating component to the first PCM, each pipe has a first end connected to the heat-generating component and a second end connected to the first PCM, wherein the pipes contain a second PCM.

### BRIEF DESCRIPTION OF THE DRAWINGS

FIG. 1 is a top perspective view of a Central Compute Unit (CCU), according to an embodiment.

FIG. 2 is a top perspective cross-sectional view of a CCU illustrating a thermal management system according to a first embodiment.

FIG. 3 is a cross-sectional view of a CCU illustrating a thermal management system according to a second embodiment.

FIG. 4A is a bottom perspective view of a portion of a CCU illustrating a thermal management system according to a third embodiment; FIG. 4B is an exploded perspective view of the CCU of FIG. 4A.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative bases for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical application. Various combinations and modifications of the features consistent with the teachings of this disclosure, however, could be desired for particular applications or implementations.

“A”, “an”, and “the” as used herein refers to both singular and plural referents unless the context clearly dictates otherwise. By way of example, “a processor” programmed to perform various functions refers to one processor programmed to perform each and every function, or more than one processor collectively programmed to perform each of the various functions.

In the context of this disclosure, terms such as “lower,” “upper,” “above,” “below,” and similar directional terms are used solely for the purpose of describing the relative positions and orientations of components as depicted in the accompanying figures. These terms are not intended to impose any limitations on the invention or its embodiments. The described orientations are illustrative and are meant to facilitate understanding of the invention as shown in the figures. It should be understood that the components of the invention can be arranged in various orientations and configurations without departing from the scope and spirit of the invention. The invention is intended to encompass all such variations and modifications that fall within the scope of the appended claims.

Furthermore, in certain embodiments, it is said that a phase change material “directly” contacts a certain component. However, the phase change material can be encapsulated within a specific film or container designed to maintain its shape and volume, ensuring that it remains stable and effective in its thermal management role. This encapsulation can be achieved using materials that are thermally conductive yet structurally supportive, such as thin metal films or specialized polymers. Despite being contained, it can be said that the phase change material “directly” contacts another component because the phase change material's encapsulating material is thin enough to allow efficient thermal conduction.

In the field of high-power electronic systems, particularly those utilized in automotive or automated vehicles, effective thermal management is important to ensure reliable operation and prevent system failures. These systems, such as System-on-Chips (SoCs) or system-in-package (SIP) modules, generate significant amounts of heat during operation, necessitating efficient cooling solutions to maintain optimal performance and prevent overheating. Traditionally, liquid cooling systems have been employed to dissipate heat from these components under normal operation. However, these systems are not without their challenges, particularly in scenarios where coolant loss occurs.

A disadvantage of existing liquid cooling systems is their vulnerability to coolant failure. In the event of a coolant leak or pump malfunction, the rapid rise in temperature can lead to a swift shutdown of the electronic components, potentially jeopardizing vehicle control and safety. This is particularly concerning in automated vehicles, where the loss of functionality in the Central Compute Unit (CCU) or other important systems can result in catastrophic outcomes. For example, some vehicles may lose complete operation of the CCU in less than 10 seconds from the moment in which the coolant system fails. While some solutions have attempted to integrate phase change materials (PCMs) within or near the cooling channels to provide additional thermal buffering, these approaches often introduce unwanted thermal resistance during typical operation, which can impede the system's cooling efficiency.

The present disclosure addresses these challenges by introducing a novel thermal management approach that integrates phase change materials in a manner that enhances cooling efficiency without compromising performance during normal operation. This system strategically places PCM in various configurations to act as a thermal buffer, absorbing excess heat during coolant failure scenarios and extending the operational window before reaching high shut-down temperatures. By doing so, the system provides a passive backup cooling solution that enhances safety and reliability, allowing for a more controlled and extended response time in the event of a cooling system failure. This approach not only mitigates the risks associated with sudden system shutdowns but also preserves optimal cooling performance under normal conditions, offering a comprehensive solution to the thermal management challenges faced by high-power electronic systems in automated vehicles.

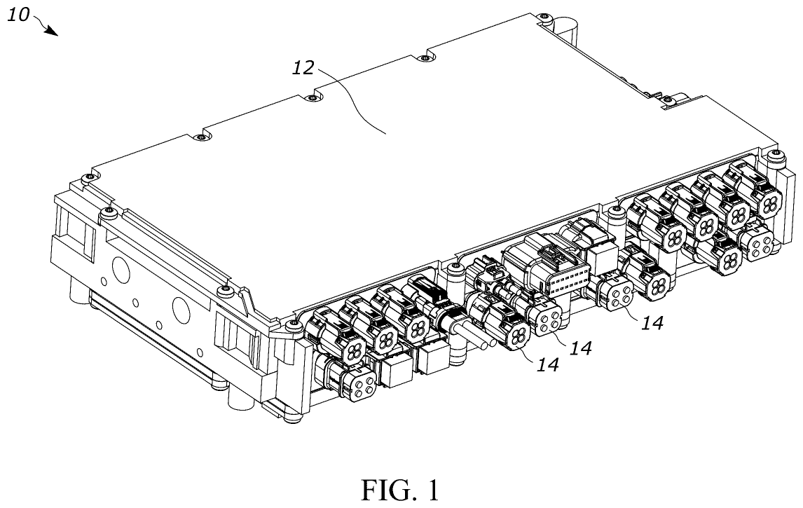

FIG. 1 illustrates a Central Compute Unit (CCU) 10, which serves as a foundational component in various electronic systems onboard automotive vehicles. In essence, the CCU can act as the “brain” of the vehicle, integrating and coordinating the functions of multiple subsystems to ensure efficient and safe operation. In embodiments, the CCU processes data from various sensors and Electronic Control Units (ECUs) distributed throughout the vehicle. This data can include information from systems such as engine control, transmission, braking, steering, and more. The CCU integrates data from different subsystems to ensure they work together harmoniously. For example, it can coordinate the actions of the engine and transmission to optimize fuel efficiency and performance. In vehicles with Advanced Driver Assistance Systems (ADAS), the CCU processes data from cameras, radar sensors, LIDAR sensors, and the like to enable features like adaptive cruise control, lane-keeping assistance, and automatic emergency braking. The CCU can also be responsible for facilitating communication between various vehicle systems, managing the user interface and infotainment systems, and managing other systems within the vehicle. Due to the amount of processing and management, the CCU 10 can output a high amount of thermal energy, and therefore must be actively cooled to assure proper operation and functionality.

While the thermal management systems disclosed herein are illustrated as applying to CCUs, it should be understood that the present disclosure is not limited to only such embodiments. For example, the thermal management systems disclosed herein can be applied to ECUs, or other modules that require active cooling. In other words, the CCU 10 illustrated here is only one embodiment in which the teachings of the thermal management system disclosed herein can apply.

The CCU 10 includes an outer housing 12, which provides structural support and protection for the internal components. The housing 12 shields the processing devices and other components from environmental factors such as dust, moisture, and mechanical impacts. This protective enclosure ensures the reliable operation of the CCU 10 under various conditions, which is important for maintaining the performance and safety of the systems that the CCU 10 controls.

Attached to the CCU 10 are electronics connectors 14, which facilitate the integration of the CCU 10 with other electronic modules and systems. These connectors 14 are designed to provide secure and efficient electrical connections, enabling the transfer of data and power between the CCU 10 and other components.

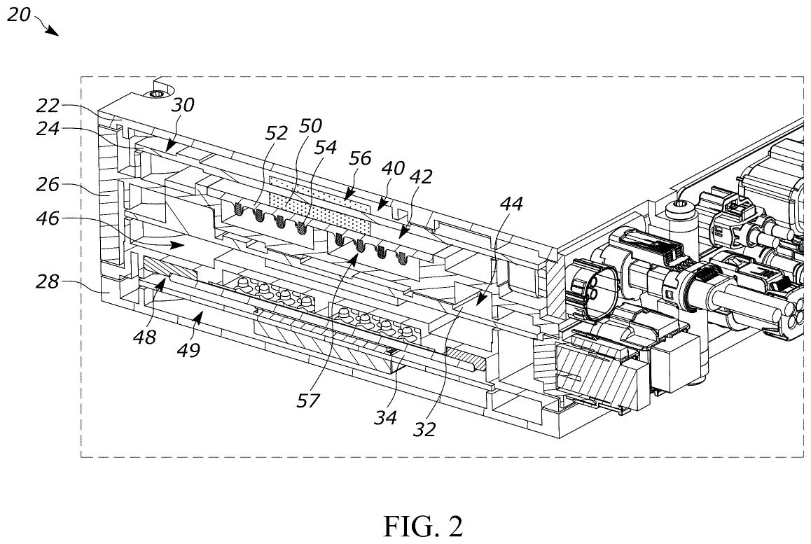

FIG. 2 is a cross-sectional view of a thermal management system for a CCU 20, according to one embodiment. This embodiment focuses on a strategic and particular location of a phase change material (PCM) relative to a heat-generating component, as will be further described below.

The CCU 20 includes an outer housing 12 that can include various sub-housings, for example a first sub-housing 22, a second sub-housing 24, a third sub-housing 26, and a fourth sub-housing 28. These sub-housings can also be referred to as sub-assemblies or sub-modules; they can be assembled together to collectively form the outer housing of the CCU 20, yet are individual components.

The sub-housings can be arranged in a stacked formation such that the first sub-housing 22 is the upper-most sub-housing, and the fourth sub-housing 28 is the lower-most housing. The second sub-housing 24 is beneath the first sub-housing 22, and the third sub-housing 26 is beneath the second sub-housing 24.

These sub-housings can also interact with a plurality of stacked PCBs. For example, the CCU 20 can include a first PCB 30, a second PCB 32 beneath the first PCB 30, and a third PCB 34 beneath the second PCB 32. Each of these PCBs can serve as a platform for mounting electronic components, including the heat-generating device described below. The PCBs can include a wide range of components, each serving specific functions to ensure the system's operation, performance, and reliability. For example, the PCBs can include microprocessors and SoCs, memory modules (e.g., Random Access Memory (RAM) and Read-Only Memory (ROM)), power management integrated circuits (PMICs), connectors and interfaces (e.g., USB, HDMI, Ethernet, etc.), temperature sensors, pressure sensors, passive components (e.g., resistors, capacitors, inductors), and the like. Any of these components that generates heat can be referred to as a “heat-generating component” which is generally and schematically illustrated by reference numeral 50. In embodiments, the heat-generating component 50 is a SIP or SoC.

The layering and stacking of the sub-housings and PCBs defines various chambers or cavities. For example, a first cavity 40 exists between the first sub-housing 22 and the first PCB 30; a second cavity 42 exists between the lower surface of the first PCB 30 and the second sub-housing 24 (or heat sink, described below); a third cavity 44 exists between the bottom of the second sub-housing 24 and the top of the second PCB 32; a fourth cavity 46 exists between the bottom of the second PCB 32 and a top of the third sub-housing 26; a fifth cavity 48 exists between a bottom of the fourth sub-housing (or another heat sink) and a top of the third PCB 34; a sixth cavity 49 exists beneath the third PCB 34 and the fourth sub-housing 28. These cavities are merely exemplary, and are meant to illustrate the spacing between various stacked components in the CCU 20 illustrated in FIG. 2.

As explained above, a heat-generating component 50 is provided on a lower side of the first PCB 30. In embodiments, the heat-generating component 50 is a SIP or SoC. Thus, an active cooling system is provided to maintain the temperature of the heat-generating component 50 and maintain proper operation. For example, a heat sink 52 can be located beneath the heat-generating component 50. The heat sink 52 can be in direct or indirect contact with the heat-generating component 50. (In the illustration shown, the heat sink 52 has an upper surface that is in direct contact with a lower surface of the heat-generating component 50.) The heat sink 52 has a plurality of pins or fins 54 extending downward away from the heat-generating component 50. A liquid coolant (e.g., water, glycol-water mixture, dielectric fluid, etc.) can be pumped or otherwise delivered to a cavity between the heat sink 52 and the second sub-housing 24 to physically contact the heat sink 52 and fins 54 for drawing heat therefrom. The fins 54 are designed to not only increase the surface area of the heat sink 52 in areas of the heat sink that contacts the fluid, but also to create turbulence in the fluid to increase the heat transfer coefficient and promote better mixing of the fluid.

As explained herein, FIG. 2 illustrates a phase change material (PCM) 56 positioned on the opposite side of the first PCB 30 from the heat-generating component 50. This configuration leverages the PCB 30 as a thermal conduit, allowing heat generated by the component 50 to be conducted through the PCB to the PCM 56. As such, the first PCB 30 can include thermal vias (e.g., copper tracks) that extend vertically through the first PCB 30 to transfer heat directly from the heat-generating component 50 to the PCM 56. The PCM 56 plays an important role in thermal management by absorbing excess heat through a phase change process, which effectively prevents rapid temperature increases that could lead to system shutdowns. By undergoing a phase change, the PCM 56 absorbs a significant amount of thermal energy, thereby lengthening the heat exchange process and providing a thermal buffer. This delay in temperature rise extends the operational window of the electronic system, allowing for a more controlled response to potential cooling system failures and enhancing the overall reliability and safety of the high-power electronic system.

This can provide significant advantages. For example, consider a scenario in an automated vehicle where the CCU is actively managing critical functions such as navigation and sensor data processing. During normal operation, the liquid cooling system efficiently dissipates heat generated by the CCU's SoC, while the PCM remains in a solid state, effectively “frozen” due to the maintained relatively low temperatures. This solid state of the PCM ensures that it is ready to absorb heat when needed. However, in the event of a coolant system failure, such as a pump malfunction or a coolant leak, the temperature within the CCU begins to rise rapidly. As the coolant flow ceases, the PCM gradually transitions from a solid to a liquid state, absorbing the excess heat generated by the SoC. This phase change process allows the PCM to absorb a substantial amount of thermal energy via latent heat without a corresponding increase in temperature, effectively acting as a thermal buffer. By doing so, the PCM prolongs the operation of the SoC, providing valuable time for the system to either restore the cooling function or execute a controlled shutdown, thereby preventing immediate overheating and potential damage to the electronic components.

The PCM 56 can refer to a container that houses the phase change material itself. The phase change material can be a solid-to-solid (Crystalline change) or, more typically, a solid-to-liquid type. The PCM can be selected from a range of substances, such as organic or non-organic or eutectic type materials which are chosen based on their phase change points and latent heat properties to optimize constant temperature heat absorption. A common organic type would be paraffin wax. The PCM phase change temperatures can be selected based on the operating profiles of the electronic heat-generating components being thermally protected. Typically the phase change temperature will be above the normal operating temperature. The normal operating temperature is controlled by the primary cooling system.

Furthermore, in this illustrated embodiment, with the PCM 56 being located on an opposite side of the PCB 30 from the heat-generating component 50 (i.e., within the first cavity 40 fluidly isolated from the bottom of the heat sink 52), the PCM 56 is not in the flow path of the coolant that interacts with the heat sink 52 and its fins 54. This placement avoids introducing any additional thermal resistance to the primary coolant path, which is responsible for efficiently dissipating heat from the heat-generating component 50. By keeping the PCM 56 out of the direct flow of the coolant, the system maintains optimal cooling performance, allowing the liquid coolant to effectively absorb and carry away heat without obstruction. By not interfering with the primary cooling mechanism, this configuration preserves the efficiency of the cooling system while providing an additional layer of thermal protection, enhancing the overall reliability and performance of the electronic system.

However, in other embodiments, the PCM can be in direct contact with the coolant.

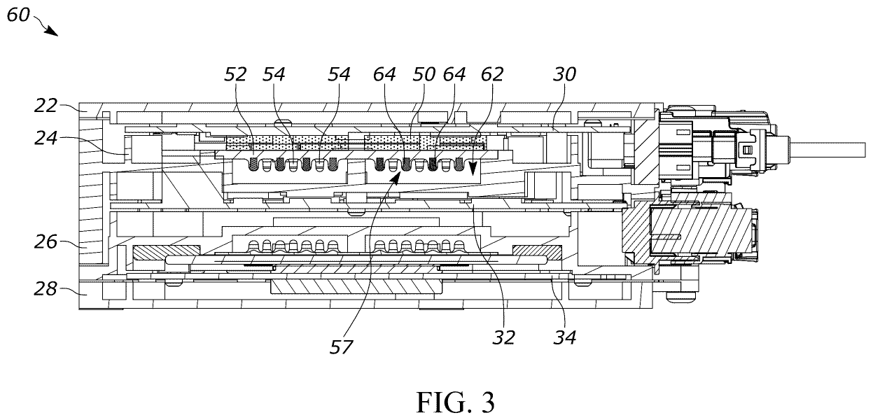

FIG. 3 illustrates such an embodiment. Here, another example of a CCU 60 is illustrated, wherein reference numbers used to identify specific components in FIG. 3 will refer to the same or a similar component already described with reference to FIG. 2, unless otherwise specified. In this embodiment, the PCM 56 is not provided above the first PCB 40. Instead, the phase change material is located in the heat sink 52 itself.

Similar to FIG. 2, here in FIG. 3, the CCU 60 includes a heat sink 52 with a plurality of pins or fins 54 that extend downward to define boundaries of fluid flow channels 57. The coolant fluid can flow within a chamber 62 defined between the lower surface of the heat sink 52 and an upper surface of the second sub-housing 24, for example. The fluid interacts with the fins 54 which create turbulence in the fluid and increase the surface area of the heat sink 52.

In this embodiment, the heat sink 52 can also include a plurality of rods 64 that contain a PCM. The rods 64 can be located directly within the fluid flow channels 57 within the chamber 62 such that the fluid directly contacts the rods 64. This configuration allows the PCM to interact dynamically with the coolant, enhancing the system's ability to manage heat during both normal operation and coolant failure scenarios. By placing the PCM rods in the fluid flow path, the system leverages the efficient heat dissipation of the coolant to facilitate efficient heat transfer to the PCM. During normal operation, the coolant flows around the PCM rods, maintaining the PCM in a solid state and ensuring it is primed to absorb heat when needed. In the event of a coolant system failure, the PCM rods begin to change phase, absorbing excess thermal energy and providing a critical thermal buffer.

The rods 64 with PCM can assume a variety of configurations. For example, in one embodiment, the rods 64 can be oriented parallel to the direction of coolant flow, allowing the fluid to efficiently transfer heat to the PCM as it passes by. Alternatively, the rods 64 can be positioned perpendicular to the flow, creating additional turbulence and enhancing heat exchange. The rods 64 can also be interspliced within the fins 54 of the heat sink, increasing the surface area for heat transfer and promoting better thermal management. This intersplicing can be achieved by weaving the rods between the fins or embedding them within the fin structure itself. Additionally, the rods 64 can vary in length and diameter, tailored to the specific thermal requirements of the system, and can be made from materials with high latent heat capacity to facilitate rapid heat absorption. Alternatively or additionally, the fins 54 themselves comprise the PCM.

The rods 64 containing the PCM can be positioned in areas that are directly vertically aligned with the heat-generating component(s) 50, ensuring efficient heat absorption from the most critical thermal zones. This alignment allows the PCM to directly interact with the heat generated by components. Alternatively, the rods can be distributed throughout the PCB, extending to areas where the heat-generating component does not directly contact the heat sink. This distribution ensures a more uniform thermal management across the entire PCB, allowing the system to effectively manage heat dissipation even in regions that are not in direct contact with the primary cooling elements.

In yet other embodiments not illustrated here, the heat sink 52 can be provided with embedded PCM that directly contacts the heat-generating component 50. For example, referring to FIG. 3, the upper surface of the heat sink 52 can be provided with the PCM such that the PCM directly contacts the bottom of the heat-generating device. Of course, as explained above, a thin encapsulating layer or film can be provided between the “direct” contact of the PCM and the heat-generating component 50. This embodiment can be provided in addition or alternative to the embodiment illustrated in FIG. 3.

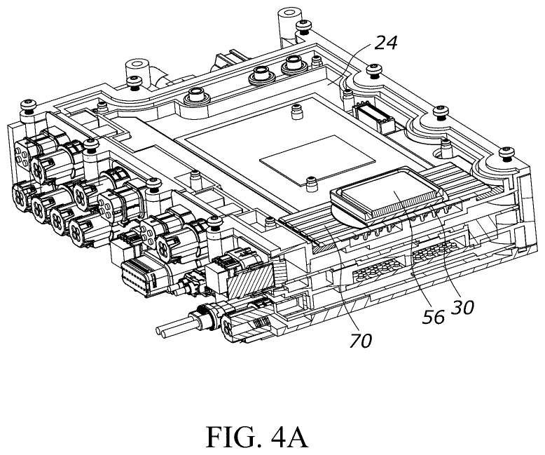

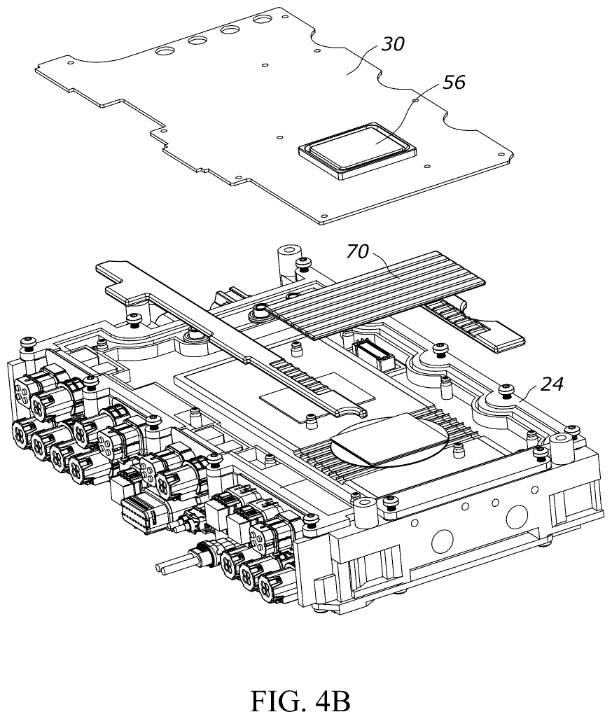

FIGS. 4A-4B illustrate yet another embodiment of the thermal management system disclosed herein. FIG. 4A provides a perspective view of a portion of the CCU (e.g., the second sub-housing 24 and the connected first PCB 30), and FIG. 4B provides an exploded view of the same, also illustrating the heat-generating component 50, a plurality of heat pipes 70, and a block of PCM 56. Together, FIGS. 4A and 4B demonstrate an innovative use of heat pipes 70 in conjunction with PCM 56 to manage heat in high-power electronic systems. The figures illustrate how the heat pipes 70 are integrated into the CCU's design, enhancing the system's ability to maintain optimal operating temperatures and prevent overheating.

In the illustrated embodiment, the heat-generating component may once again be a SIP module or SoC, and may be mounted on the lower side of the PCB 30, above the upper surface of the second sub-housing 24. The heat-generating component 50 is in thermal communication with the heat pipes 70, which facilitates the rapid transfer of heat away from the component via bi-phase properties. The heat pipes 70 are configured to efficiently transfer heat from the heat-generating component 50 to the PCM 56. The heat pipe 70 operates on the principle of phase change within the structure, typically involving the evaporation and condensation of a working fluid. This process enables the heat pipe 70 to provide a low-resistance thermal path, ensuring rapid and efficient heat transfer. The heat pipe 70 is strategically positioned to direct heat towards the PCM 56, which acts as a thermal buffer during scenarios of coolant failure.

The PCM 56 may be a separate container or block of PCM, and is positioned at one end of the heat pipes 70, serving as a thermal buffer that absorbs excess heat through a phase change process. Once again, the PCM 56 is selected based on its phase change point and latent heat capacity to optimize heat absorption and dissipation. During typical operation, the PCM 56 can remain in a solid state, ready to absorb heat when needed. In the event of a coolant system failure, the PCM 56 undergoes a phase change (e.g., melts), absorbing a significant amount of thermal energy without a corresponding increase in temperature. This process effectively delays the temperature rise of the heat-generating component 50, providing an important safety margin and extending the operational window before reaching high temperatures. Using heat pipes rapid heat spreading properties allows for a PCM 56 to be situated away from the electronic components being cooled. Situating the PCM remotely can enable a larger quantity of the PCM to be used, further enhancing the operational window during coolant system failures.

Constructed from materials with high thermal conductivity, such as copper or aluminum, the heat pipes 70 allow for rapid heat transfer along their length. The interior of each heat pipe 70 can be lined with a wicking material, such as sintered metal (e.g., copper) powder, which aids in the capillary action necessary for the working fluid to circulate. Operating on the principle of phase change and capillary action, the heat pipes contain a small amount of working fluid, such as water, ethanol, or ammonia. This fluid evaporates at the hot end, near the heat-generating component 50, and condenses at the cooler end, near the PCM 56. This phase change process allows the heat pipe to transfer heat with minimal thermal resistance, providing an efficient and low-resistance thermal path. The design of the heat pipes 70 ensures that they can move large amounts of heat with a small temperature difference between the hot and cold ends, enhancing the overall efficiency of the thermal management system.

The heat pipes 70 can be manufactured in various shapes and sizes to fit specific design requirements. They can be straight, bent, or flattened to accommodate space constraints and optimize thermal performance within the electronic system. The heat pipes 70 can be effectively coupled to the housing 24 using several methods to ensure optimal thermal conductivity and mechanical stability. One approach involves pressing the heat pipes forcefully into pre-formed grooves within the housing 24. This method provides a secure fit and maximizes the surface contact between the heat pipes and the housing, enhancing heat transfer efficiency. Alternatively, the heat pipes can be soldered to the housing, creating a robust thermal and mechanical bond. Soldering ensures excellent thermal conductivity and provides a durable connection that can withstand thermal cycling and mechanical stresses. Another method involves using epoxy to bond the heat pipes to the housing. This approach offers flexibility in positioning and can accommodate slight variations in alignment. The epoxy acts as both an adhesive and a thermal interface material, ensuring good thermal contact while providing mechanical support. Each of these coupling methods can be selected based on specific design requirements, manufacturing capabilities, and performance criteria.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

What is claimed is:

1. A thermal management system for vehicle electronics, the thermal management system comprising:
a printed circuit board (PCB) having an upper side and a lower side;
a heat-generating component having an upper side and a lower side, wherein the upper side of the heat-generating component is mounted on the lower side of the PCB; and
a phase change material (PCM) positioned on the upper side of the PCB at a location that is vertically aligned with the heat-generating component, wherein the PCM absorbs heat conducted through the PCB from the heat-generating component such that the PCM is configured to protect the heat-generating component upon failure of a separate cooling system.

2. The thermal management system of claim 1, further comprising:
a heat sink contacting the lower side of the heat-generating component, wherein the heat sink defines cooling channels beneath the heat-generating component, wherein the cooling channels are configured to facilitate the flow of coolant directly underneath the heat-generating component to absorb and dissipate heat generated by the heat-generating component;
wherein the PCM enhances thermal management of a Central Compute Unit (CCU) without introducing thermal resistance in the flow of coolant.

3. The thermal management system of claim 2, further comprising a second PCM embedded in the heat sink.

4. The thermal management system of claim 3, wherein the heat sink includes a plurality of fins that extend into or define boundaries of the cooling channels, and wherein at least some of the fins comprise the second PCM.

5. The thermal management system of claim 1, wherein the heat-generating component is a System-on-Chip (SoC) or a System-in-Package (SiP) module.

6. The thermal management system of claim 1, further comprising a housing that encapsulates the PCB, the heat-generating component, and the PCM, wherein the housing includes a first sub-housing located above the PCM, a second sub-housing located beneath the PCB, and a second PCB beneath the second sub-housing.

7. A thermal management system for vehicle electronics, the thermal management system comprising:
a printed circuit board (PCB) having an upper side and a lower side;
a heat-generating component having an upper side and a lower side, wherein the upper side of the heat-generating component is mounted on the lower side of the PCB;
a heat sink contacting the lower side of the heat-generating component, wherein the heat sink defines cooling channels beneath the heat-generating component, wherein the cooling channels are configured to facilitate the flow of coolant directly underneath the heat-generating component to absorb and dissipate heat generated by the heat-generating component; and
a phase change material (PCM) embedded in the heat sink such that the PCM is configured to protect the heat-generating component upon failure of a separate cooling system.

8. The thermal management system of claim 7, wherein the PCM is embedded in the heat sink at a location that is vertically aligned with the heat-generating component.

9. The thermal management system of claim 8, wherein a portion of the PCM directly contacts the heat-generating component.

10. The thermal management system of claim 7, further comprising a plurality of rods located in the cooling channels, wherein the rods comprise the PCM.

11. The thermal management system of claim 10, wherein the heat sink includes a plurality of fins that extend into or define boundaries of the cooling channels, wherein the plurality of rods are located in spaces between the plurality of fins.

12. The thermal management system of claim 7, wherein the heat sink includes a plurality of fins that extend into or define boundaries of the cooling channels, and wherein at least some of the plurality of fins comprise the PCM.

13. The thermal management system of claim 7, further comprising a second PCM positioned on the upper side of the PCB at a location that is vertically aligned with the heat-generating component, wherein the second PCM absorbs heat conducted through the PCB from the heat-generating component.

14. The thermal management system of claim 13, wherein the PCB includes thermal vias that thermally couple the heat-generating component to the second PCM.

15. The thermal management system of claim 7, further comprising a plurality of heat pipes connecting the heat-generating component to a second PCM, wherein each heat pipe has a first end connected to the heat-generating component and a second end connected to the second PCM.

16. The thermal management system of claim 15, wherein the plurality of heat pipes contain a third PCM.

17. A thermal management system for vehicle electronics, the thermal management system comprising:
a printed circuit board (PCB) having an upper side and a lower side;
a housing located beneath the PCB and defining a cavity therebetween;
a heat-generating component located within the cavity and mounted on the lower side of the PCB;
a first phase change material (PCM) located between the housing and the PCB; and
a plurality of heat pipes connecting the heat-generating component to the first PCM, each heat pipe has a first end connected to the heat-generating component and a second end connected to the first PCM, wherein the plurality of heat pipes contain a second PCM.

18. The thermal management system of claim 17, wherein the plurality of heat pipes contain a working fluid selected from the group consisting of water, ethanol, and ammonia, which facilitates phase change within the plurality of heat pipes to enhance heat transfer efficiency.

19. The thermal management system of claim 17, further comprising a third PCM positioned on the upper side of the PCB at a location that is vertically aligned with the heat-generating component, wherein the third PCM absorbs heat conducted through the PCB from the heat-generating component.

20. The thermal management system of claim 17, further comprising:
a heat sink beneath the heat-generating component, wherein the heat sink defines cooling channels beneath the heat-generating component, wherein the cooling channels are configured to facilitate the flow of coolant directly underneath the heat-generating component to absorb and dissipate heat generated by the heat-generating component; and
a third PCM embedded in the heat sink.
